(19) United States
(12) Patent Application Publication
(10) Pub. No.: US 2022/0278675 A1
(43) Pub. Date: Sep. 1, 2022

(54) LOW POWER SEQUENTIAL CIRCUIT APPARATUS

(71) Applicant: Intel Corporation, Santa Clara, CA (US)

(72) Inventors: Tzvika LUSTMAN, Megido (IL); Avi YONA, Tirat Carmel (IL); Yizhar TSUR, Petah Tikva (IL)

(21) Appl. No.: 17/625,706

(22) PCT Filed: Jul. 8, 2020
(86) PCT No.: PCT/US2020/041273

§ 371 Date: Jan. 7, 2022

Related U.S. Application Data
(60) Provisional application No. 62/884,087, filed on Aug. 7, 2019.

(51) Int. Cl. H03K 3/3562; H03K 3/012; H03K 3/037

(52) U.S. Cl. CPC H03K 3/35625; H03K 3/012; H03K 3/0372

(57) ABSTRACT

A latch and/or flip-flop with reduced dynamic capacitance for the clock node. Power associated with the clock node is reduced without timing impact. Merely two clock devices and merely the signal on the clock input pin toggles when the data does not change. As such, power is reduced. Further, the latch is interrupted-based with no contention or jamming issues. The latch can be configured as master and slave latches to form a flip-flop.

### CLAIM OF PRIORITY

This application is a PCT application that claims the benefit of priority to U.S. Provisional Patent Application No. 62/884,087, filed on Aug. 7, 2019, titled “Low Power Sequential Circuit Apparatus,” and which is incorporated by reference in entirety.

### BACKGROUND

Major part of power consumption under modern chip designs is clock related. For example, the power invested for clock distribution and sequential clock toggling results in most of power consumption in a chip. Process technology node continues the trend of increase in transistor current (Ids) for a given transistor gate capacitance (Cgate). This trend also increases power for such clock distribution and sequential clock circuits that normally use small sized (e.g., smaller width) devices.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a typical latch.

FIG. 2 illustrates an AOI latch.

FIG. 3 illustrates a vector structure using legacy latch and shared clock inverter.

FIG. 4 illustrates a schematic of an active high roadster latch, in accordance with some embodiments.

FIG. 5 illustrates a plot showing simulation of the active high roadster latch, in accordance with some embodiments.

FIG. 6 illustrates a plot showing simulation of the roadster latch, in accordance with some embodiments.

FIG. 7 illustrates a plot showing savings in dynamic capacitance using the roadster latch compared to other latches, in accordance with some embodiments.

FIG. 8 illustrates a flip-flop with a roadster latch, in accordance with some embodiments.

FIG. 9 illustrates a smart device or a computer system or an SoC (System-on-Chip) according to the apparatus, method, and system of various embodiments.

### DETAILED DESCRIPTION

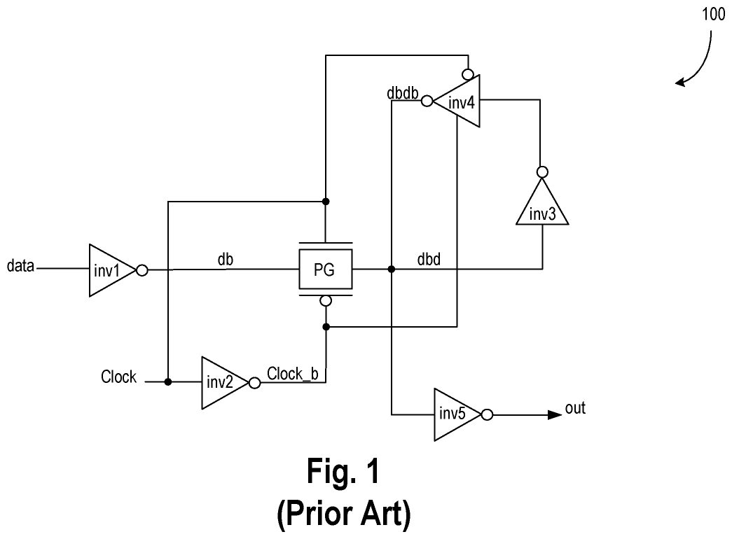

FIG. 1 illustrates a typical latch 100 having inverters inv1, inv2, inv3, inv4, and inv5; nodes data, clock, dbd, dbdb, and out; and pass-gate PG coupled together as shown. Inverter inv4 is a tri-statable inverter.

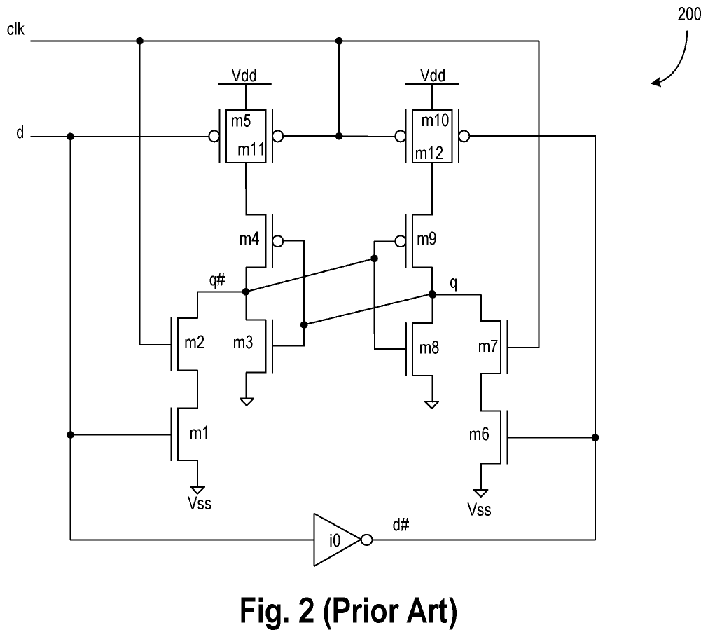

FIG. 2 illustrates an AOI (and-or-inverter) latch 200 with n-type transistors m1, m2, m3, m6, m7, and m8; p-type transistors m4, m9, m5, m9, m10, m11, and m12; nodes data (d), clock (clk), q, q #, d #; and inverter i0 coupled together as shown. For both latches of FIG. 1 and FIG. 2, the clock dynamic capacitance ranges from 20% to 30% of the entire latch dynamic capacitance.

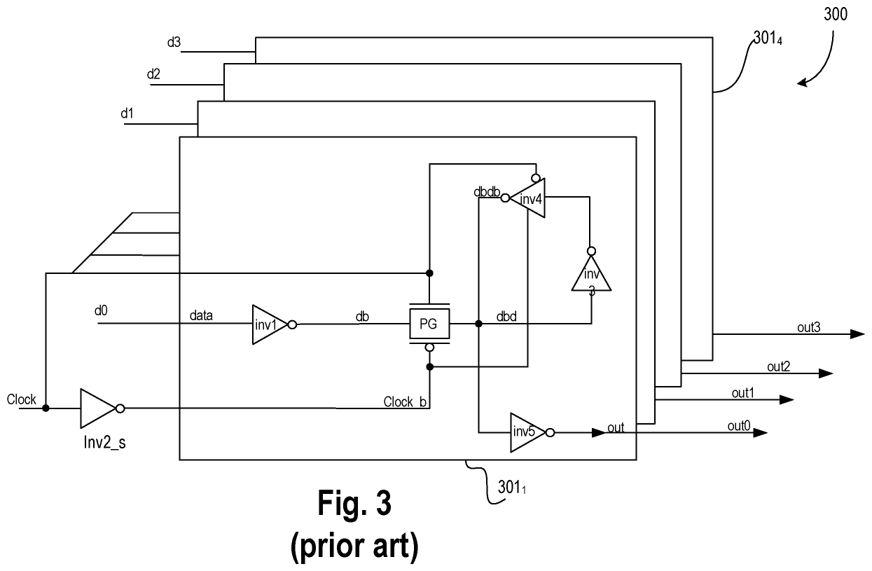

FIG. 3 illustrates a vector structure 300 using legacy latch and shared clock inverter. In this example, four latches 301₁ to 301₄ of FIG. 1 are vectored that share a common clock inverter inv2_s. Each latch receives its corresponding data—d0, d1, d2, and d3, respectively, and generate their corresponding output—out0, out1, out2, and out3 respectively.

Table 1 summarizes the disadvantages of the latch designs of FIGS. 1-3.

TABLE 1

| Type | Clock Power | Cin saving | Pros/cons |
|---|---|---|---|
| Vector cells | Cdyn ~= N*4 + 2 | Minor saving | Approximately |
| | N reflects the number of bits | | 15% cell level |
| | | | clock cdyn saving. |
| | | | Approximate |
| | | | neutral clock |
| | | | capacitance |
| | | | small delay |
| | | | degradation |
| AOI | Cdyn ~= 4 | None | Bigger data Cdyn |
| | * 4 clock devices on the input | | Bigger pin cap on |
| | | | data |
| | | | Slow cell |
| | | | Leakage increase. |

From Table 1, it can be derived that vector cells savings is up to 15% on cell-level dynamic capacitance (Cdyn), and clock effect capacitance (Ceff) stays approximately the same. It can also be derived from Table 1 that AOI of FIG. 2 is not efficient in terms of clock and data input pin capacitance and timing behavior.

In some embodiments, a latch and/or flip-flop is described with reduced dynamic capacitance for the clock node. The power reduction associated with the clock node is reduced without timing impact. Here, merely two clock devices and merely the signal on the clock input pin toggles when the data does not change. As such, power is reduced. Further, the latch circuit of various embodiments is interrupted-based with no contention or jamming issues. The latch circuit of various embodiments can be configured as master and slave latches to form a flip-flop.

In some embodiments, the latch comprises: an inverter to receive a data input and to generate an inverted data. The latch comprises a clock circuitry comprising at most two transistors of different conductivity types. The latch further comprises a first driver coupled to the clock circuitry and an input of the inverter; and a second driver coupled to the clock circuitry and an output of the inverter. In some embodiments, the latch comprises a keeper circuitry coupled to an output of the first driver and an output of the second driver. The latch further comprises a memory circuitry coupled to the output of the first driver and the output of the second driver, and to the keeper circuitry.

In some embodiments, the clock circuitry comprises: a first n-type transistor coupled to the first driver and the second driver; and a first p-type transistor coupled to the keeper circuitry, wherein gate terminals of the first n-type transistor and the first p-type transistor receive an input clock. In some embodiments, the first driver comprises: a second n-type transistor coupled to the first n-type transistor of the clock circuitry; and a second p-type transistor coupled in series with the second n-type transistor, wherein gate terminals of the second n-type transistor and the second p-type transistor are coupled to the input of the inverter, wherein drain terminals of the second p-type transistor and the second n-type transistor is coupled to the keeper circuitry and the memory circuitry.

In some embodiments, the second driver comprises: a third n-type transistor coupled to the first n-type transistor of the clock circuitry; and a third p-type transistor coupled in series with the third n-type transistor, wherein gate terminals of the third n-type transistor and the third p-type transistor are coupled to the output of the inverter, wherein drain terminals of the third p-type transistor and the third n-type transistor is coupled to the keeper circuitry and the memory circuitry.

In some embodiments, the keeper circuitry comprises: a fourth p-type transistor coupled to the first p-type transistor of the clock circuitry, and to the drain terminals of the second p-type transistor and the second n-type transistor of the first driver; and a fifth p-type transistor coupled to first p-type transistor of the clock circuitry, and to the drain terminals of the third p-type transistor and the third n-type transistor of the second driver.

In some embodiments, the memory circuitry comprises: a first NAND gate having a first input coupled to the drain terminals of the second p-type transistor and the second n-type transistor of the first driver, and a second input coupled to a gate terminal of the fourth p-type transistor of the keeper circuitry; and a second NAND gate having a first input coupled to the drain terminals of the third p-type transistor and the third n-type transistor of the second driver, and to an output of the first NAND gate, and a second input coupled to a gate terminal of the fifth p-type transistor of the keeper circuitry.

In some embodiments, the latch comprises a third NAND gate having a first input coupled to the drain terminals of the third p-type transistor and the third n-type transistor of the second driver, and an output of the first NAND gate; and a second input coupled to the second input of the second NAND gate.

In some embodiments, the latch comprises a driver coupled to the memory circuitry, wherein the driver provides an output of the latch. In some embodiments, the memory circuitry comprises cross-coupled NAND or NOR gates, wherein the cross-coupled NAND or NOR gates are coupled to the first driver, second driver, and the keeper circuitry. In some embodiments, the keeper circuitry comprises two transistors of a same conductivity type.

There are several technical effects of various embodiments. For example, latch cell power is reduced which results in large power savings for most intellectual property (IP) block. For instance, 65% reduction in cell clock Cdyn maps to approximately 15% Cdyn savings on most IP levels. The savings in power consumption is a factor of clock-to-date activity factor (AF)—the higher the AF, the higher the power savings. The term AF is also used to define a ratio between clock transition and data transition. For example, clock active cycle has two transitions (e.g., rise and fall). If the data toggle once every cycle, then AF=2(clock)/1(data)=2. Other technical effects are evident from the various figures and embodiments.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “adjacent” here generally refers to a position of a thing being next to (e.g., immediately next to or close to with one or more things between them) or adjoining another thing (e.g., abutting it).

The term “circuit” or “module” may refer to one or more passive and/or active components that are arranged to cooperate with one another to provide a desired function.

The term “signal” may refer to at least one current signal, voltage signal, magnetic signal, or data/clock signal. The meaning of “a,” “an,” and “the” include plural references. The meaning of “in” includes “in” and “on.”

The term “scaling” generally refers to converting a design (schematic and layout) from one process technology to another process technology and may be subsequently being reduced in layout area. In some cases, scaling also refers to upsizing a design from one process technology to another process technology and may be subsequently increasing layout area. The term “scaling” generally also refers to downsizing or upsizing layout and devices within the same technology node. The term “scaling” may also refer to adjusting (e.g., slowing down or speeding up—i.e. scaling down, or scaling up respectively) of a signal frequency relative to another parameter, for example, power supply level. The terms “substantially,” “close,” “approximately,” “near,” and “about,” generally refer to being within +/−10% of a target value.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The terms “left,” “right.” “front,” “back,” “top,” “bottom,” “over,” “under,” and the like in the description and in the claims, if any, are used for descriptive purposes and not necessarily for describing permanent relative positions.

It is pointed out that those elements of the figures having the same reference numbers (or names) as the elements of any other figure can operate or function in any manner similar to that described but are not limited to such.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors (BJT PNP/NPN), BiCMOS, CMOS, etc., may be used without departing from the scope of the disclosure.

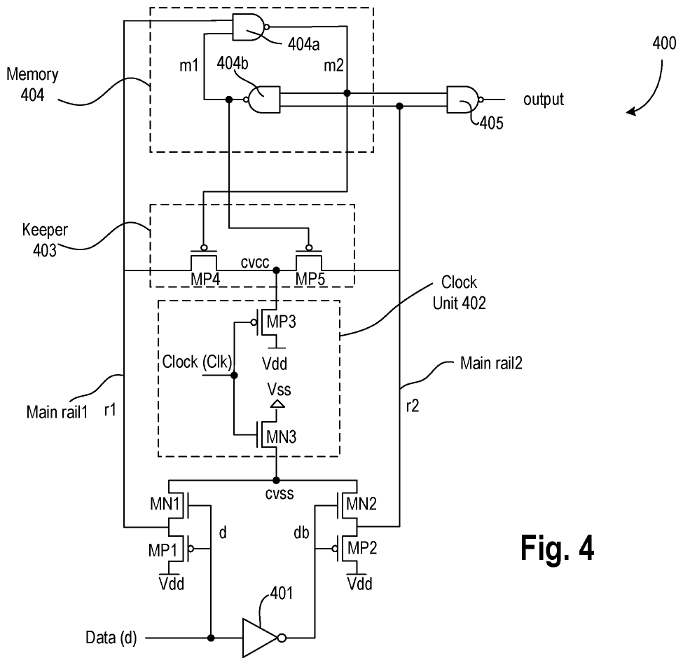

FIG. 4 illustrates schematic of an active high roadster latch 400, in accordance with some embodiments. Latch 400 comprises data inverter 401, clock unit 402, keeper 403, memory 404, and output driver 405. Input data (d) is inverted by inverter 401 to generate db. Here, signal names and node names are interchangeably used. For example, db may represent signal db or node db depending on the context of the sentence. Signals and “db” are driven to main rail1 (r1) and main rail2 (r2), respectively, via inverter-like drivers. These inverter-like drivers comprise a first driver and a second driver. The first driver provides inverted version of data d to main rail r1, and comprise p-type device MP1 and n-type device MN1, where the MN1 device is coupled to virtual ground cvss from clock unit 402. The second driver provides inverted version of db to main rail r2, and comprises p-type device MP2 and n-type device MN2, where the MN2 device is coupled to the virtual ground cvss from clock unit 402.

In various embodiments, clock unit 402 comprises two devices—n-type device MN3 and p-type device MP3. The gate terminals of MN3 and MP3 receive the clock (clk). Transistor MN3 when turned on, provides the virtual ground cvss. Transistor MP3 when turned on, provides the virtual supply cvcc to keeper 403. In some embodiments, keeper 403 comprises p-type devices MP4 and MP5 coupled in series with a common node cvcc. Each of devices MP4 and MP5 are coupled to main rail1 r1 and main rail2 r2, respectively. The gate terminals of MP4 and MP5 are coupled to nodes m1 and m2 of memory 404.

In some embodiments, memory 404 comprises a cross-coupled set-reset (SR) latch. In some embodiments, memory 404 comprises NAND gate 404a and 404b coupled such that the output (m2) of NAND gate 404a drives an input of NAND gate 404b, and the output (m1) of NAND gate 404b drives an input of NAND gate 404a. The output of latch 400 (also referred to as roadster latch) is driven by output driver 405. In some embodiments, driver 405 is a NAND gate coupled to main rail2 and node m2. While the embodiments describe memory 404 as cross-coupled NAND gates, other logic gates can also be used. For example, cross-coupled NOR gates can replace the cross-coupled NAND gates. Depending of the design requirements of latch 400 (e.g., transparent high or transparent low), p-type and n-type devise of clock unit 402 and keeper 403 can be swapped, and memory 404 can be implemented as NOR gate.

Compared to typical latch 100, roadster latch 400 of FIG. 4 has two clock devices (e.g., MP3 and MN3) compared to six clock devices of typical latch 100. The memory (set-reset (SR) memory 404) is controlled directly by r1 and r2, which are the two main rails. Table 2 shows the logic values on nodes m1 and m2 depending on values on nodes r1 and r2.

TABLE 2

| r1 | r2 | m1 | m2 |
|---|---|---|---|
| 0 | 1 | 0 | 1 |
| 1 | 0 | 1 | 0 |
| 1 | 1 | Keep | Keep |
| 0 | 0 | 1 | 1 |

Keeper 403 is controlled by signals on nodes m1, m2, and clock (clk). Keeper 403 keeps the relevant rails (r1 or r2) on “high” when clock is low. Here, the not allowed state is avoided due to the dependency on signal on nodes m1 and m2. Given that one of the memory nets (m1 or m2) is ‘0’, it always reflects ‘1’ on the other memory node. Table 3 shows the logic values on nodes m1, m2, and clock, and corresponding values on rails r1 and r2.

TABLE 3

| clk | m1 | m2 | r1 | r2 |
|---|---|---|---|---|
| 0 | 0 | 1 | Float | 1 |
| 0 | 1 | 0 | 1 | Float |

| | | | |
|---|---|---|---|
| 1 | Mutex | Float | Float |

| | | | |
|---|---|---|---|
| Φ | 0 | 0 | State not allowed |

| | | | | |
|---|---|---|---|---|
| Φ | 1 | 1 | Float | Float |

Table 4 illustrates the data transparency functionality of the latch, in accordance with various embodiments.

TABLE 4

| Data D | clk | r1 | r2 |
|---|---|---|---|
| 0 | 1 | 1 | 0 |
| 1 | 1 | 0 | 1 |
| 0 | 0 | 1 | Float |
| 1 | 0 | Float | 1 |

When the clock is at high logic level, the data signal propagates onto main rail r1 (having data bar) and main rail r2 (having data). When the clock clk is at low logic level, the state is kept. In this case, logic 1 is propagated to rails r1/r2.

Table 5 illustrates the memory behavior and transparency-to-output function.

| Type | Connection | Data vs. Out | Delay |
|---|---|---|---|
| NAND | m1, r1 | Same polarity | Skew rise/fall |
| NAND | m2. r2 | Inverted polarity | Balanced rise/fall |

The mutually exclusive (mutex) conditions on nodes m1 and m2 is ensured by design, in accordance with some embodiments. Electric wise, overlap of “1” is expected during data transition when clock is “1”. At the end of the write operation (e.g., after setup time), one of the memories will store zero, the other will store “one”. That behavior keeps at least one of the keeper devices to be disconnected. As such, drain to source path is avoided from r1 and r2 through keeper 403.

Floating node(s) is part of r1/r2 behavior during keep state. For example, r1 can be floating merely if m1 is zero and while the cell is in keep state. When r1 floats, it implies that m1 is zero. The concern of floating gate is eliminated at the NAND gate 404a and/or 404b because the other input is zero (e.g., m1 in that case). Note that the NAND gates 404a and/or 404b of SR memory 404 NAND is a receiver on the rail. Having the related memory at “0” avoids rush-through current.

The delay characteristics are described by Table 5.

TABLE 5

| | | |
|---|---|---|
| Structure | Legacy | Roadster |

| | | | |
|---|---|---|---|
| Power type | Fast | Fast | Power |
| Read type | inverter | NAND | NAND |
| Data-to-output | 31.3 | 32.5 | 35.6 |
| (picoseconds (ps)) | | | |
| Data-to-output | 0 | 1.2 | 4.3 |
| difference (ps) | | | |
| Clock-to-output | 0 | −0.1 | 2.1 |
| difference (ps) | | | |

Listed in Table 5, delay comparison for both: data-to-output and clock-to-output. Roadster latch of various embodiments is compared to the legacy latch of FIG. 1. Note that roadster latch is compatible w/ the fastest sequential. Regarding delay and slope characteristics. Roadster offers lighter version that maintain robust design (listed in the Table 4 as power flavor). By having bigger devices (e.g., large width), the roadster latch observes less variation.

Table 6 describes the setup and hold timing characteristics of roadster latch 400 compared to legacy latch 100. Roadster latch 400 exhibits improved setup time and hold time. Legacy internal clock inverter inv2 introduces additional skew penalty.

TABLE 6

| check | transition | set by condition: | rdstr | legacy | diff |
|---|---|---|---|---|---|
| setup | data fall | AF + x ps | 10.4 | 9.2 | 1.2 |
| setup | data rise | AF + x ps | 7.4 | 10.2 | −2.8 |
| hold | data fall | legacy by glitch, roadster by | −4 | −5.4 | 1.4 |
| | | failure | | | |
| hold | data rise | Legacy by glitch, roadster by | −1 | −2.4 | 1.4 |
| | | failure | | | |

The dynamic capacitance (Cdyn) and leakage characteristics are described by Table 7.

TABLE 7

| | |
|---|---|
| Legacy | Roadster |

| Type | Units | Fast | Fast | Power |
|---|---|---|---|---|
| Data | % | 0% | 104% | 96% |
| Clock | % | 0% | −65% | −70% |
| Total | % | 0% | 59% | 52% |
| Core width (Z) | | Yes | Yes | Yes |
| limits | | | | |

As shown in Table 7, clock Cdyn reduces by 70%, data Cdyn increases by 96%, for example. Note that legacy latch Cdyn (clock): Cdyn (Data) is 1:3. Cell leakage increased by 75% vs. legacy latch.

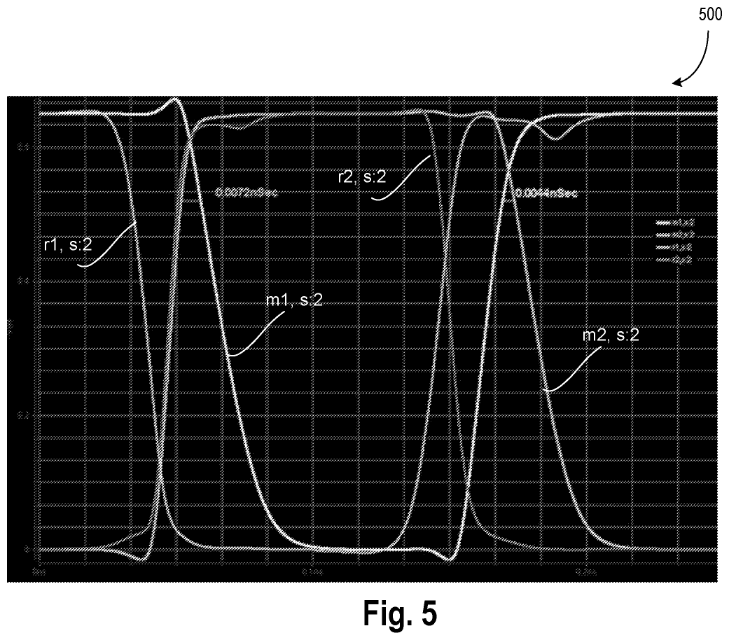

FIG. 5 illustrates plot 500 showing simulation of the active high roadster latch, in accordance with some embodiments. In this plot, the delays are marked 80% to 80% of m1/m2 (‘1’ overlap). Logic mutex on d and db nodes can be violated electric wise for given transition time of the data and the inverted data net (db). In that case, overlap of “1” and “0” is observed during data toggling. There is no side effect during write operation. During keep operation, for a limited time, there may be conductive connection (e.g., source to drain through cvss). With float that starts with “0” (e.g. r1), it will be connected to the keep “1” (e.g., r2) for limited time. In that case, the keeper drives “1” to the floating net. Note that r1 will rise also by the data write p-type device (beyond the keeper).

Similar keeper write can be seen on the most common legacy flop where the master gets locked and the slave “attacks” the master. Legacy FF (flip-flop) design is sized to avoid write back. Compared to the legacy FF, the latch of various embodiments observes less severity. In general, that constraint defines the keeper minimum width Z.

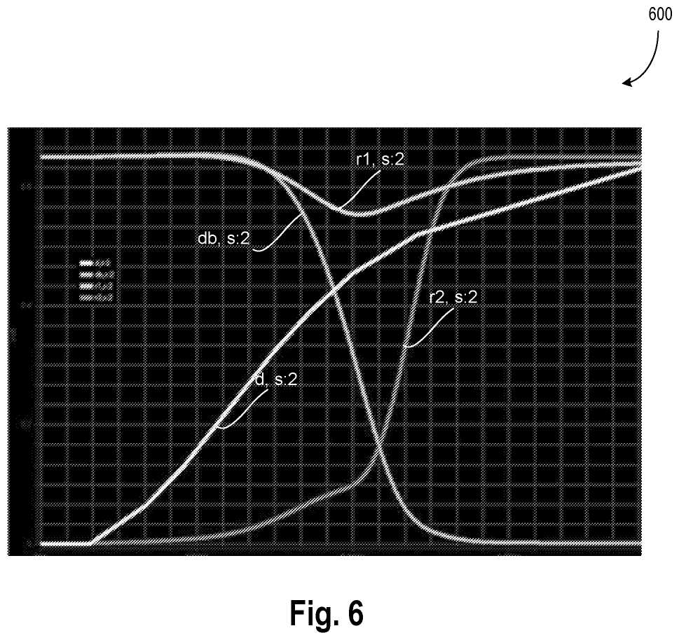

FIG. 6 illustrates plot 600 showing simulation of roadster latch 400, in accordance with some embodiments. This plot shows signals on r1 and r2 nodes with respect to data transition under keep state (e.g., when clock is zero).

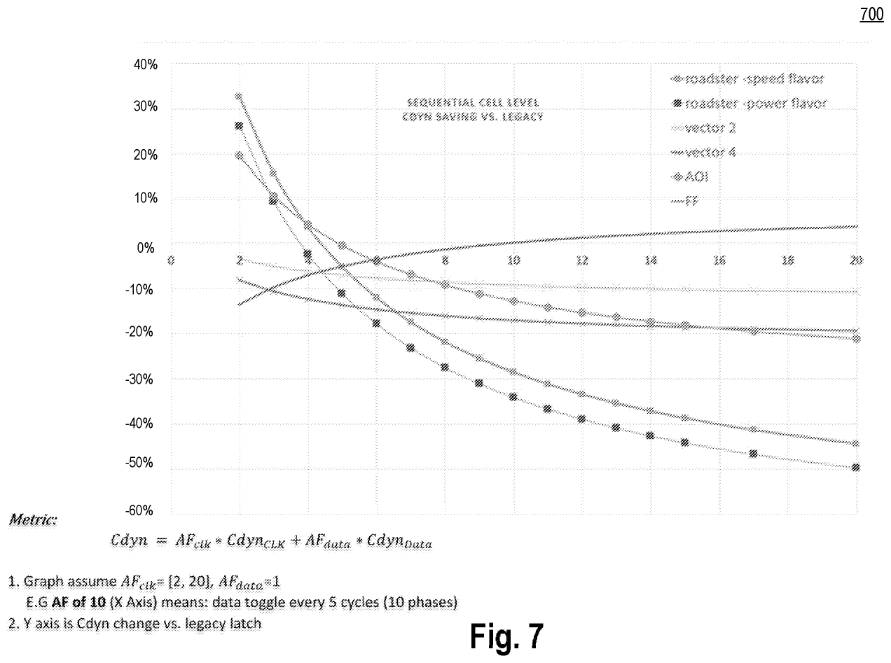

FIG. 7 illustrates plot 700 showing savings in dynamic capacitance using the roadster latch compared to other latches, in accordance with some embodiments. AF term used to define the ratio between clock transition and data transition. If the data toggles once every clock cycle, AF=2(clock)/1(data)=2. Breakeven point is AF of 4, where data changes every 2 cycles. In this example, sequential Cdyn decreases by 34% for AF of 10; legacy vector gains 8% for 2 bits and 17% for 4 bits (depending on AF); and break even vs. vector is AF of 5.

Clock input capacitance for the latch of various embodiments is reduced by 38% to 47% as illustrated by Table 8. In this example, data capacitance increases by 58% to 45%. The ratio of legacy Cdyn (Clock)/Cdyn (Data) is 1.15.

TABLE 8

| | |
|---|---|
| Legacy | Roadster |

| Type | Units | Default | Fast | Power |
|---|---|---|---|---|
| Data | % | 0% | 58% | 45% |
| Clock | % | 0% | −38% | 47% |
| Core width (Z) | | Yes | Yes | Yes |
| limits | | | | |

Table 9 illustrates the area and layout impact of the roadster latch 400 compared to layout of legacy latch 100. Larger size of roadster latch 400 results in less random/systematic variation.

TABLE 9

| Type | Legacy | Roadster | Increase % |
|---|---|---|---|
| Core | 100% | 150% | 50% |
| Scan | 250% | 300% | 20% |
| Functional Safety | 340% | 390% | 14.7% |
| Scan | | | |

While the embodiment of FIG. 4 is illustrated as active high latch, the same structure or circuit can be modified to implement an active low latch. For example, by replacing n-type transistors to p-type transistors, and by replacing p-type transistors to n-type transistors, active low roadster latch can be realized.

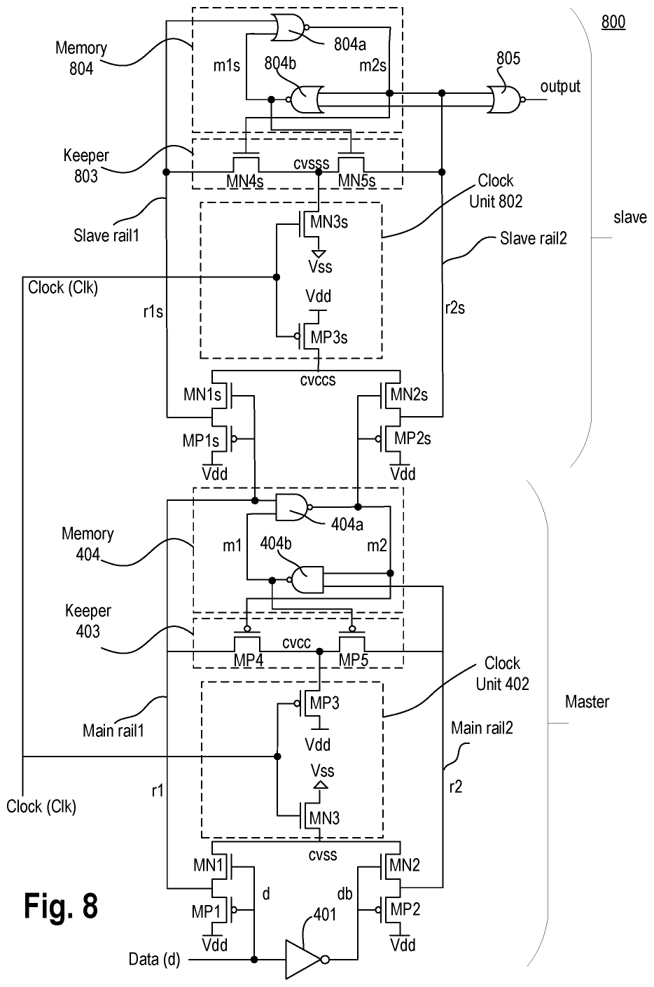

FIG. 8 illustrates flip-flop 800 with a roadster latch, in accordance with some embodiments. In this case, on the master latch, the output drive is removed and nets m1 and m2 act as output and are connects as inputs to a slave. At the slave side, the data inverter is removed and nets m1 and m2 are connected to originally named nodes d and db. In some embodiments, optional sharing can take place on the clock devices of the master and slave. For example, write clock of master and keep clock of slave can be shared. Here, master side is substantially same as latch 400, expect that driver 405 is removed.

The slave side comprises clock unit 802, keeper 403, memory 804, and output driver 805. Signals on nodes m1 and m1 are driven to slave rail1 (r1s) and slave rail2 (rs2), respectively, via inverter-like drivers. These inverter-like drivers comprise a first driver and a second driver. The first driver provides inverted version of data on node m1 to slave rail r1s, and comprises p-type device MP1s and n-type device MN1s, where the MN1s device is coupled to virtual supply cvccs from clock unit 802. The second driver provides inverted version of data on mode m2 to slave rail r2s, and comprises p-type device MP2s and n-type device MN2s, where the MN2s device is coupled to the virtual supply cvccs from clock unit 802.

In various embodiments, clock unit 802 comprises two devices—n-type device MN3s and p-type device MP3s. The gate terminals of MN3s and MP3s receive the clock (clk). Transistor MN3s when turned on, provides the virtual ground cvsss to keeper 803. Transistor MP3s, when turned on, provide the virtual supply cvcc. In some embodiments, keeper 803 comprises n-type devices MN4s and MN5s coupled in series with a common node cvsss. Each of devices MN4s and MN5s are coupled to slave rail1 r1s and slave rail2 r2s, respectively. The gate terminals of MN4s and MN5s are coupled to nodes m1 and m2 of memory 404.

In some embodiments, memory 804 comprises a cross-coupled set-reset (SR) latch. In some embodiments, memory 804 comprises NOR gate 804a and 404b coupled such that the output (m2s) of NOR gate 804a drives an input of NOR gate 804b, and the output (nits) of NOR gate 804b drives an input of NOR gate 804a. The output of slave latch is driven out driver 805. In some embodiments, driver 805 is a NOR gate coupled to slave rail2 and node m2s.

While the embodiments describe memory 804 as cross-coupled NOR gates, other logic gates can also be used. For example, cross-coupled NAND gates can replace the cross-coupled NOR gates. Depending on the design requirements of flip-flop 800 (e.g., rising edge triggered or falling edge trigged), p-type and n-type devise of clock unit 402 and/or 802 and keeper 403 and/or 803 can be swapped, and memory 404 and/or 804 can be implemented as NAND gate.

The roadster latch design of various embodiments is also applicable to scan flop topology implementation and embedded logic latches and flip-flops. Latch 400 and/or flip-flop 800 can be configured as vectored latches or flip-flops.

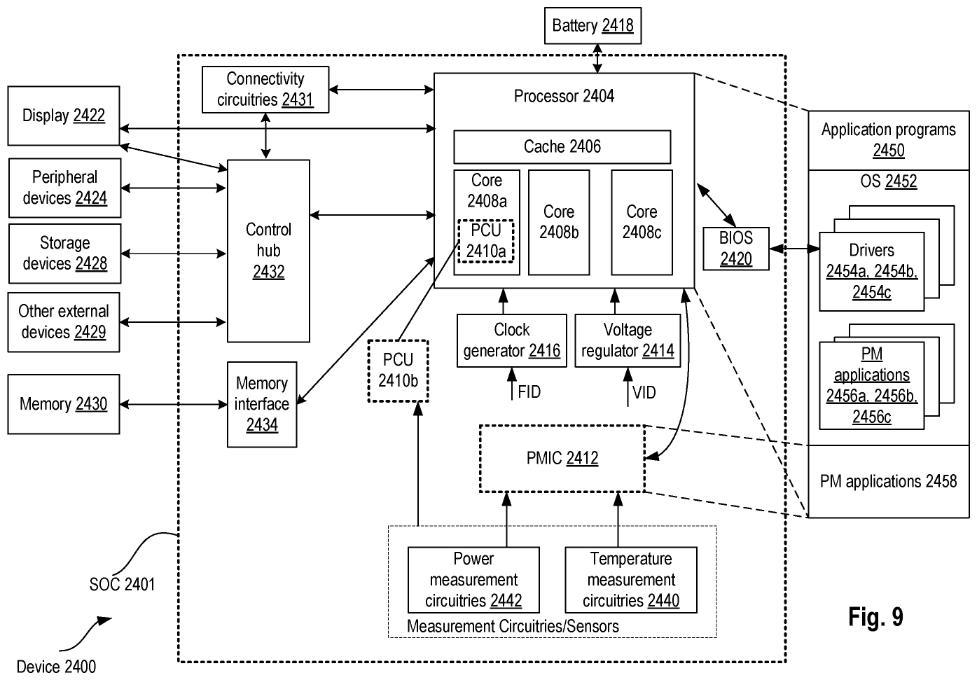

FIG. 9 illustrates a smart device or a computer system or an SoC (System-on-Chip) according to the apparatus, method, and system of various embodiments.

In some embodiments, device 2400 represents an appropriate computing device, such as a computing tablet, a mobile phone or smart-phone, a laptop, a desktop, an Internet-of-Things (IOT) device, a server, a wearable device, a set-top box, a wireless-enabled e-reader, or the like. It will be understood that certain components are shown generally, and not all components of such a device are shown in device 2400. Any component of device 2400 can include the latch and/or flip-flop of various embodiments.

In an example, the device 2400 comprises an SoC (System-on-Chip) 2401. An example boundary of the SOC 2401 is illustrated using dotted lines in FIG. 9, with some example components being illustrated to be included within SOC 2401—however, SOC 2401 may include any appropriate components of device 2400.

In some embodiments, device 2400 includes processor 2404. Processor 2404 can include one or more physical devices, such as microprocessors, application processors, microcontrollers, programmable logic devices, processing cores, or other processing means. The processing operations performed by processor 2404 include the execution of an operating platform or operating system on which applications and/or device functions are executed. The processing operations include operations related to I/O (input/output) with a human user or with other devices, operations related to power management, operations related to connecting computing device 2400 to another device, and/or the like. The processing operations may also include operations related to audio I/O and/or display I/O.

In some embodiments, processor 2404 includes multiple processing cores (also referred to as cores) 2408a, 2408b, 2408c. Although merely three cores 2408a, 2408b, 2408c are illustrated in FIG. 9, processor 2404 may include any other appropriate number of processing cores, e.g., tens, or even hundreds of processing cores. Processor cores 2408a, 2408b, 2408c may be implemented on a single integrated circuit (IC) chip. Moreover, the chip may include one or more shared and/or private caches, buses or interconnections, graphics and/or memory controllers, or other components.

In some embodiments, processor 2404 includes cache 2406. In an example, sections of cache 2406 may be dedicated to individual cores 2408 (e.g., a first section of cache 2406 dedicated to core 2408a, a second section of cache 2406 dedicated to core 2408b, and so on). In an example, one or more sections of cache 2406 may be shared among two or more of cores 2408. Cache 2406 may be split in different levels, e.g., level 1 (L1) cache, level 2 (L2) cache, level 3 (L3) cache, etc.

In some embodiments, processor core 2404 may include a fetch unit to fetch instructions (including instructions with conditional branches) for execution by the core 2404. The instructions may be fetched from any storage devices such as the memory 2430. Processor core 2404 may also include a decode unit to decode the fetched instruction. For example, the decode unit may decode the fetched instruction into a plurality of micro-operations. Processor core 2404 may include a schedule unit to perform various operations associated with storing decoded instructions. For example, the schedule unit may hold data from the decode unit until the instructions are ready for dispatch, e.g., until all source values of a decoded instruction become available. In one embodiment, the schedule unit may schedule and/or issue (or dispatch) decoded instructions to an execution unit for execution.

The execution unit may execute the dispatched instructions after they are decoded (e.g., by the decode unit) and dispatched (e.g., by the schedule unit). In an embodiment, the execution unit may include more than one execution unit (such as an imaging computational unit, a graphics computational unit, a general-purpose computational unit, etc.). The execution unit may also perform various arithmetic operations such as addition, subtraction, multiplication, and/or division, and may include one or more an arithmetic logic units (ALUs). In an embodiment, a co-processor (not shown) may perform various arithmetic operations in conjunction with the execution unit.

Further, execution unit may execute instructions out-of-order. Hence, processor core 2404 may be an out-of-order processor core in one embodiment. Processor core 2404 may also include a retirement unit. The retirement unit may retire executed instructions after they are committed. In an embodiment, retirement of the executed instructions may result in processor state being committed from the execution of the instructions, physical registers used by the instructions being de-allocated, etc. Processor core 2404 may also include a bus unit to enable communication between components of processor core 2404 and other components via one or more buses. Processor core 2404 may also include one or more registers to store data accessed by various components of the core 2404 (such as values related to assigned app priorities and/or sub-system states (modes) association.

In some embodiments, device 2400 comprises connectivity circuitries 2431. For example, connectivity circuitries 2431 includes hardware devices (e.g., wireless and/or wired connectors and communication hardware) and/or software components (e.g., drivers, protocol stacks), e.g., to enable device 2400 to communicate with external devices. Device 2400 may be separate from the external devices, such as other computing devices, wireless access points or base stations, etc.

In an example, connectivity circuitries 2431 may include multiple different types of connectivity. To generalize, the connectivity circuitries 2431 may include cellular connectivity circuitries, wireless connectivity circuitries, etc. Cellular connectivity circuitries of connectivity circuitries 2431 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, 3rd Generation Partnership Project (3GPP) Universal Mobile Telecommunications Systems (UMTS) system or variations or derivatives, 3GPP Long-Term Evolution (LTE) system or variations or derivatives, 3GPP LTE-Advanced (LTE-A) system or variations or derivatives, Fifth Generation (5G) wireless system or variations or derivatives, 5G mobile networks system or variations or derivatives, 5G New Radio (NR) system or variations or derivatives, or other cellular service standards. Wireless connectivity circuitries (or wireless interface) of the connectivity circuitries 2431 refers to wireless connectivity that is not cellular, and can include personal area networks (such as Bluetooth, Near Field, etc.), local area networks (such as Wi-Fi), and/or wide area networks (such as WiMax), and/or other wireless communication. In an example, connectivity circuitries 2431 may include a network interface, such as a wired or wireless interface, e.g., so that a system embodiment may be incorporated into a wireless device, for example, a cell phone or personal digital assistant.

In some embodiments, device 2400 comprises control hub 2432, which represents hardware devices and/or software components related to interaction with one or more I/O devices. For example, processor 2404 may communicate with one or more of display 2422, one or more peripheral devices 2424, storage devices 2428, one or more other external devices 2429, etc., via control hub 2432. Control hub 2432 may be a chipset, a Platform Control Hub (PCH), and/or the like.

For example, control hub 2432 illustrates one or more connection points for additional devices that connect to device 2400, e.g., through which a user might interact with the system. For example, devices (e.g., devices 2429) that can be attached to device 2400 include microphone devices, speaker or stereo systems, audio devices, video systems or other display devices, keyboard or keypad devices, or other I/O devices for use with specific applications such as card readers or other devices.

As mentioned above, control hub 2432 can interact with audio devices, display 2422, etc. For example, input through a microphone or other audio device can provide input or commands for one or more applications or functions of device 2400. Additionally, audio output can be provided instead of, or in addition to display output. In another example, if display 2422 includes a touch screen, display 2422 also acts as an input device, which can be at least partially managed by control hub 2432. There can also be additional buttons or switches on computing device 2400 to provide I/O functions managed by control hub 2432. In one embodiment, control hub 2432 manages devices such as accelerometers, cameras, light sensors or other environmental sensors, or other hardware that can be included in device 2400. The input can be part of direct user interaction, as well as providing environmental input to the system to influence its operations (such as filtering for noise, adjusting displays for brightness detection, applying a flash for a camera, or other features).

In some embodiments, control hub 2432 may couple to various devices using any appropriate communication protocol, e.g., PCIe (Peripheral Component Interconnect Express), USB (Universal Serial Bus), Thunderbolt, High Definition Multimedia Interface (HDMI), Firewire, etc.

In some embodiments, display 2422 represents hardware (e.g., display devices) and software (e.g., drivers) components that provide a visual and/or tactile display for a user to interact with device 2400. Display 2422 may include a display interface, a display screen, and/or hardware device used to provide a display to a user. In some embodiments, display 2422 includes a touch screen (or touch pad) device that provides both output and input to a user. In an example, display 2422 may communicate directly with the processor 2404. Display 2422 can be one or more of an internal display device, as in a mobile electronic device or a laptop device or an external display device attached via a display interface (e.g., DisplayPort, etc.). In one embodiment display 2422 can be a head mounted display (HMD) such as a stereoscopic display device for use in virtual reality (VR) applications or augmented reality (AR) applications.

In some embodiments, and although not illustrated in the figure, in addition to (or instead of) processor 2404, device 2400 may include Graphics Processing Unit (GPU) comprising one or more graphics processing cores, which may control one or more aspects of displaying contents on display 2422.

Control hub 2432 (or platform controller hub) may include hardware interfaces and connectors, as well as software components (e.g., drivers, protocol stacks) to make peripheral connections, e.g., to peripheral devices 2424.

It will be understood that device 2400 could both be a peripheral device to other computing devices, as well as have peripheral devices connected to it. Device 2400 may have a “docking” connector to connect to other computing devices for purposes such as managing (e.g., downloading and/or uploading, changing, synchronizing) content on device 2400. Additionally, a docking connector can allow device 2400 to connect to certain peripherals that allow computing device 2400 to control content output, for example, to audiovisual or other systems.

In addition to a proprietary docking connector or other proprietary connection hardware, device 2400 can make peripheral connections via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, connectivity circuitries 2431 may be coupled to control hub 2432, e.g., in addition to, or instead of, being coupled directly to the processor 2404. In some embodiments, display 2422 may be coupled to control hub 2432, e.g., in addition to, or instead of, being coupled directly to processor 2404.

In some embodiments, device 2400 comprises memory 2430 coupled to processor 2404 via memory interface 2434. Memory 2430 includes memory devices for storing information in device 2400.

In some embodiments, memory 2430 includes apparatus to maintain stable clocking as described with reference to various embodiments. Memory can include nonvolatile (state does not change if power to the memory device is interrupted) and/or volatile (state is indeterminate if power to the memory device is interrupted) memory devices. Memory device 2430 can be a dynamic random access memory (DRAM) device, a static random access memory (SRAM) device, flash memory device, phase-change memory device, or some other memory device having suitable performance to serve as process memory. In one embodiment, memory 2430 can operate as system memory for device 2400, to store data and instructions for use when the one or more processors 2404 executes an application or process. Memory 2430 can store application data, user data, music, photos, documents, or other data, as well as system data (whether long-term or temporary) related to the execution of the applications and functions of device 2400.

Elements of various embodiments and examples are also provided as a machine-readable medium (e.g., memory 2430) for storing the computer-executable instructions (e.g., instructions to implement any other processes discussed herein). The machine-readable medium (e.g., memory 2430) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

In some embodiments, device 2400 comprises temperature measurement circuitries 2440, e.g., for measuring temperature of various components of device 2400. In an example, temperature measurement circuitries 2440 may be embedded, or coupled or attached to various components, whose temperature are to be measured and monitored. For example, temperature measurement circuitries 2440 may measure temperature of (or within) one or more of cores 2408a, 2408b, 2408c, voltage regulator 2414, memory 2430, a mother-board of SOC 2401, and/or any appropriate component of device 2400.

In some embodiments, device 2400 comprises power measurement circuitries 2442, e.g., for measuring power consumed by one or more components of the device 2400. In an example, in addition to, or instead of, measuring power, the power measurement circuitries 2442 may measure voltage and/or current. In an example, the power measurement circuitries 2442 may be embedded, or coupled or attached to various components, whose power, voltage, and/or current consumption are to be measured and monitored. For example, power measurement circuitries 2442 may measure power, current and/or voltage supplied by one or more voltage regulators 2414, power supplied to SOC 2401, power supplied to device 2400, power consumed by processor 2404 (or any other component) of device 2400, etc.

In some embodiments, device 2400 comprises one or more voltage regulator circuitries, generally referred to as voltage regulator (VR) 2414. VR 2414 generates signals at appropriate voltage levels, which may be supplied to operate any appropriate components of the device 2400. Merely as an example, VR 2414 is illustrated to be supplying signals to processor 2404 of device 2400. In some embodiments, VR 2414 receives one or more Voltage Identification (VID) signals, and generates the voltage signal at an appropriate level, based on the VID signals. Various type of VRs may be utilized for the VR 2414. For example, VR 2414 may include a “buck” VR, “boost” VR, a combination of buck and boost VRs, low dropout (LDO) regulators, switching DC-DC regulators, constant-on-time controller based DC-DC regulator, etc. Buck VR is generally used in power delivery applications in which an input voltage needs to be transformed to an output voltage in a ratio that is smaller than unity. Boost VR is generally used in power delivery applications in which an input voltage needs to be transformed to an output voltage in a ratio that is larger than unity. In some embodiments, each processor core has its own VR, which is controlled by PCU 2410a/b and/or PMIC 2412. In some embodiments, each core has a network of distributed LDOs to provide efficient control for power management. The LDOs can be digital, analog, or a combination of digital or analog LDOs. In some embodiments, VR 2414 includes current tracking apparatus to measure current through power supply rail(s).

In some embodiments, device 2400 comprises one or more clock generator circuitries, generally referred to as clock generator 2416. Clock generator 2416 generates clock signals at appropriate frequency levels, which may be supplied to any appropriate components of device 2400. Merely as an example, clock generator 2416 is illustrated to be supplying clock signals to processor 2404 of device 2400. In some embodiments, clock generator 2416 receives one or more Frequency Identification (FID) signals, and generates the clock signals at an appropriate frequency, based on the FID signals.

In some embodiments, device 2400 comprises battery 2418 supplying power to various components of device 2400. Merely as an example, battery 2418 is illustrated to be supplying power to processor 2404. Although not illustrated in the figures, device 2400 may comprise a charging circuitry, e.g., to recharge the battery, based on Alternating Current (AC) power supply received from an AC adapter.

In some embodiments, device 2400 comprises Power Control Unit (PCU) 2410 (also referred to as Power Management Unit (PMU), Power Controller, etc.). In an example, some sections of PCU 2410 may be implemented by one or more processing cores 2408, and these sections of PCU 2410 are symbolically illustrated using a dotted box and labelled PCU 2410a. In an example, some other sections of PCU 2410 may be implemented outside the processing cores 2408, and these sections of PCU 2410 are symbolically illustrated using a dotted box and labelled as PCU 2410b. PCU 2410 may implement various power management operations for device 2400. PCU 2410 may include hardware interfaces, hardware circuitries, connectors, registers, etc., as well as software components (e.g., drivers, protocol stacks), to implement various power management operations for device 2400.

In some embodiments, device 2400 comprises Power Management Integrated Circuit (PMIC) 2412, e.g., to implement various power management operations for device 2400. In some embodiments, PMIC 2412 is a Reconfigurable Power Management ICs (RPMICs) and/or an IMVP (Intel® Mobile Voltage Positioning). In an example, the PMIC is within an IC chip separate from processor 2404. The may implement various power management operations for device 2400. PMIC 2412 may include hardware interfaces, hardware circuitries, connectors, registers, etc., as well as software components (e.g., drivers, protocol stacks), to implement various power management operations for device 2400.

In an example, device 2400 comprises one or both PCU 2410 or PMIC 2412. In an example, any one of PCU 2410 or PMIC 2412 may be absent in device 2400, and hence, these components are illustrated using dotted lines.

Various power management operations of device 2400 may be performed by PCU 2410, by PMIC 2412, or by a combination of PCU 2410 and PMIC 2412. For example, PCU 2410 and/or PMIC 2412 may select a power state (e.g., P-state) for various components of device 2400. For example, PCU 2410 and/or PMIC 2412 may select a power state (e.g., in accordance with the ACPI (Advanced Configuration and Power Interface) specification) for various components of device 2400. Merely as an example, PCU 2410 and/or PMIC 2412 may cause various components of the device 2400 to transition to a sleep state, to an active state, to an appropriate C state (e.g., CO state, or another appropriate C state, in accordance with the ACPI specification), etc. In an example, PCU 2410 and/or PMIC 2412 may control a voltage output by VR 2414 and/or a frequency of a clock signal output by the clock generator, e.g., by outputting the VID signal and/or the FID signal, respectively. In an example, PCU 2410 and/or PMIC 2412 may control battery power usage, charging of battery 2418, and features related to power saving operation.

The clock generator 2416 can comprise a phase locked loop (PLL), frequency locked loop (FLL), or any suitable clock source. In some embodiments, each core of processor 2404 has its own clock source. As such, each core can operate at a frequency independent of the frequency of operation of the other core. In some embodiments, PCU 2410 and/or PMIC 2412 performs adaptive or dynamic frequency scaling or adjustment. For example, clock frequency of a processor core can be increased if the core is not operating at its maximum power consumption threshold or limit. In some embodiments, PCU 2410 and/or PMIC 2412 determines the operating condition of each core of a processor, and opportunistically adjusts frequency and/or power supply voltage of that core without the core clocking source (e.g., PLL of that core) losing lock when the PCU 2410 and/or PMIC 2412 determines that the core is operating below a target performance level. For example, if a core is drawing current from a power supply rail less than a total current allocated for that core or processor 2404, then PCU 2410 and/or PMIC 2412 can temporality increase the power draw for that core or processor 2404 (e.g., by increasing clock frequency and/or power supply voltage level) so that the core or processor 2404 can perform at higher performance level. As such, voltage and/or frequency can be increased temporality for processor 2404 without violating product reliability.

In an example, PCU 2410 and/or PMIC 2412 may perform power management operations, e.g., based at least in part on receiving measurements from power measurement circuitries 2442, temperature measurement circuitries 2440, charge level of battery 2418, and/or any other appropriate information that may be used for power management. To that end, PMIC 2412 is communicatively coupled to one or more sensors to sense/detect various values/variations in one or more factors having an effect on power/thermal behavior of the system/platform. Examples of the one or more factors include electrical current, voltage droop, temperature, operating frequency, operating voltage, power consumption, inter-core communication activity, etc. One or more of these sensors may be provided in physical proximity (and/or thermal contact/coupling) with one or more components or logic/IP blocks of a computing system. Additionally, sensor(s) may be directly coupled to PCU 2410 and/or PMIC 2412 in at least one embodiment to allow PCU 2410 and/or PMIC 2412 to manage processor core energy at least in part based on value(s) detected by one or more of the sensors.

Also illustrated is an example software stack of device 2400 (although not all elements of the software stack are illustrated). Merely as an example, processors 2404 may execute application programs 2450, Operating System (OS) 2452, one or more Power Management (PM) specific application programs (e.g., generically referred to as PM applications 2458), and/or the like. PM applications 2458 may also be executed by the PCU 2410 and/or PMIC 2412. OS 2452 may also include one or more PM applications 2456a, 2456b, 2456c. The OS 2452 may also include various drivers 2454a, 2454b, 2454c, etc., some of which may be specific for power management purposes. In some embodiments, device 2400 may further comprise a Basic Input/Output System (BIOS) 2420. BIOS 2420 may communicate with OS 2452 (e.g., via one or more drivers 2454), communicate with processors 2404, etc.

For example, one or more of PM applications 2458, 2456, drivers 2454, BIOS 2420, etc. may be used to implement power management specific tasks, e.g., to control voltage and/or frequency of various components of device 2400, to control wake-up state, sleep state, and/or any other appropriate power state of various components of device 2400, control battery power usage, charging of the battery 2418, features related to power saving operation, etc.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

Various embodiments described herein are illustrated as examples. The features of these examples can be combined with one another in any suitable way. These examples include:

Example 1: A latch comprising: an inverter to receive a data input and to generate an inverted data; a clock circuitry comprising at most two transistors of different conductivity types; a first driver coupled to the clock circuitry and an input of the inverter; a second driver coupled to the clock circuitry and an output of the inverter; a keeper circuitry coupled to an output of the first driver and an output of the second driver; and a memory circuitry coupled to the output of the first driver and the output of the second driver, and to the keeper circuitry.

Example 2: The latch of example 1, wherein the clock circuitry comprises: a first n-type transistor coupled to the first driver and the second driver; and a first p-type transistor coupled to the keeper circuitry, wherein gate terminals of the first n-type transistor and the first p-type transistor receive an input clock.

Example 3: The latch of example 2, wherein the first driver comprises: a second n-type transistor coupled to the first n-type transistor of the clock circuitry; and a second p-type transistor coupled in series with the second n-type transistor, wherein gate terminals of the second n-type transistor and the second p-type transistor are coupled to the input of the inverter, wherein drain terminals of the second p-type transistor and the second n-type transistor are coupled to the keeper circuitry and the memory circuitry.

Example 4: The latch of example 2, wherein the second driver comprises: a third n-type transistor coupled to the first n-type transistor of the clock circuitry; and a third p-type transistor coupled in series with the third n-type transistor, wherein gate terminals of the third n-type transistor and the third p-type transistor are coupled to the output of the inverter, wherein drain terminals of the third p-type transistor and the third n-type transistor is coupled to the keeper circuitry and the memory circuitry.

Example 5: The latch of example 4, wherein the keeper circuitry comprises: a fourth p-type transistor coupled to the first p-type transistor of the clock circuitry, and to the drain terminals of the second p-type transistor and the second n-type transistor of the first driver; and a fifth p-type transistor coupled to first p-type transistor of the clock circuitry, and to the drain terminals of the third p-type transistor and the third n-type transistor of the second driver.

Example 6: The latch of example 5, wherein the memory circuitry comprises: a first NAND gate having a first input coupled to the drain terminals of the second p-type transistor and the second n-type transistor of the first driver, and a second input coupled to a gate terminal of the fourth p-type transistor of the keeper circuitry; and a second NAND gate having a first input coupled to the drain terminals of the third p-type transistor and the third n-type transistor of the second driver, and to an output of the first NAND gate, and a second input coupled to a gate terminal of the fifth p-type transistor of the keeper circuitry.

Example 7: The latch of example 6 comprises a third NAND gate having a first input coupled to the drain terminals of the third p-type transistor and the third n-type transistor of the second driver, and an output of the first NAND gate; and a second input coupled to the second input of the second NAND gate.

Example 8: The latch according to any one of examples 1 to 7 comprises a driver coupled to the memory circuitry, wherein the driver provides an output of the latch.

Example 9: The latch according to any one of examples 1 to 7, wherein the memory circuitry comprises cross-coupled NAND or NOR gates, wherein the cross-coupled NAND or NOR gates are coupled to the first driver, second driver, and the keeper circuitry.

Example 10: The latch according to any one of examples 1 to 7, wherein the keeper circuitry comprises two transistors of a same conductivity type.

Example 11: A latch comprising: a clock circuitry comprising at most two transistors of different conductivity types; a keeper circuitry coupled to the clock circuitry; a memory circuitry coupled to the keeper circuitry; and a driver coupled to the memory circuitry, wherein the driver provides an output of the latch.

Example 12: The latch of example 11 comprises: an inverter to receive a data input and to generate an inverted data; a first driver coupled to the clock circuitry and an input of the inverter; and a second driver coupled to the clock circuitry and an output of the inverter, wherein the first driver and the second driver are coupled to the clock circuitry, the keeper circuitry, and the memory circuitry.

Example 13: The latch of example 12 wherein the keeper circuitry is coupled to an output of the first driver and an output of the second driver.

Example 14: The latch of example 12, wherein the memory circuitry coupled to the output of the first driver and the output of the second driver, and to the keeper circuitry.

Example 15: The latch of example 12, wherein the memory circuitry comprises cross-coupled NAND or NOR gates, wherein the cross-coupled NAND or NOR gates are coupled to the first driver, second driver, and the keeper circuitry.

Example 16: The latch of example 12, wherein the clock circuitry comprises: a first n-type transistor coupled to the first driver and the second driver; and a first p-type transistor coupled to the keeper circuitry, wherein gate terminals of the first n-type transistor and the first p-type transistor receive an input clock.

Example 17: The latch of example 16, wherein the first driver comprises: a second n-type transistor coupled to the first n-type transistor of the clock circuitry; and a second p-type transistor coupled in series with the second n-type transistor, wherein gate terminals of the second n-type transistor and the second p-type transistor are coupled to the input of the inverter, wherein drain terminals of the second p-type transistor and the second n-type transistor is coupled to the keeper circuitry and the memory circuitry.

Example 18: The latch of example 17, wherein the second driver comprises: a third n-type transistor coupled to the first n-type transistor of the clock circuitry; and a third p-type transistor coupled in series with the third n-type transistor, wherein gate terminals of the third n-type transistor and the third p-type transistor are coupled to the output of the inverter, wherein drain terminals of the third p-type transistor and the third n-type transistor is coupled to the keeper circuitry and the memory circuitry.

Example 19: The latch according to any one of examples 11 to 18, wherein the keeper circuitry comprises two transistors of a same conductivity type.

Example 20: A system comprising: a processor; a memory coupled to the processor; and a wireless interface communicatively coupled to the processor, wherein the processor includes a latch according to any one of examples 1 to 10.

Example 21: A system comprising: a processor; a memory coupled to the processor; and a wireless interface communicatively coupled to the processor, wherein the processor includes a latch according to any one of examples 12 to 18.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1-21. (canceled)

22. A latch comprising:
an inverter to receive a data input and to generate an inverted data;
a clock circuitry comprising at most two transistors of different conductivity types;
a first driver coupled to the clock circuitry and an input of the inverter;
a second driver coupled to the clock circuitry and an output of the inverter;
a keeper circuitry coupled to an output of the first driver and an output of the second driver; and
a memory circuitry coupled to the output of the first driver and the output of the second driver, and to the keeper circuitry.

23. The latch of claim 22, wherein the clock circuitry comprises:
a first n-type transistor coupled to the first driver and the second driver; and
a first p-type transistor coupled to the keeper circuitry, wherein gate terminals of the first n-type transistor and the first p-type transistor receive an input clock.

24. The latch of claim 23, wherein the first driver comprises:
a second n-type transistor coupled to the first n-type transistor of the clock circuitry; and
a second p-type transistor coupled in series with the second n-type transistor, wherein gate terminals of the second n-type transistor and the second p-type transistor are coupled to the input of the inverter, wherein drain terminals of the second p-type transistor and the second n-type transistor are coupled to the keeper circuitry and the memory circuitry.

25. The latch of claim 23, wherein the second driver comprises:
a third n-type transistor coupled to the first n-type transistor of the clock circuitry; and
a third p-type transistor coupled in series with the third n-type transistor, wherein gate terminals of the third n-type transistor and the third p-type transistor are coupled to the output of the inverter, wherein drain terminals of the third p-type transistor and the third n-type transistor is coupled to the keeper circuitry and the memory circuitry.

26. The latch of claim 25, wherein the keeper circuitry comprises:
a fourth p-type transistor coupled to the first p-type transistor of the clock circuitry, and to the drain terminals of the second p-type transistor and the second n-type transistor of the first driver; and
a fifth p-type transistor coupled to first p-type transistor of the clock circuitry, and to the drain terminals of the third p-type transistor and the third n-type transistor of the second driver.

27. The latch of claim 26, wherein the memory circuitry comprises:
a first NAND gate having a first input coupled to the drain terminals of the second p-type transistor and the second n-type transistor of the first driver, and a second input coupled to a gate terminal of the fourth p-type transistor of the keeper circuitry; and
a second NAND gate having a first input coupled to the drain terminals of the third p-type transistor and the third n-type transistor of the second driver, and to an output of the first NAND gate, and a second input coupled to a gate terminal of the fifth p-type transistor of the keeper circuitry.

28. The latch of claim 27, further comprising a third NAND gate having a first input coupled to the drain terminals of the third p-type transistor and the third n-type transistor of the second driver, and an output of the first NAND gate; and a second input coupled to the second input of the second NAND gate.

29. The latch of claim 22, further comprising a third driver coupled to the memory circuitry, wherein the third driver is to provide an output of the latch.

30. The latch of claim 22, wherein the memory circuitry comprises cross-coupled NAND or NOR gates, and wherein the cross-coupled NAND or NOR gates are coupled to the first driver, second driver, and the keeper circuitry.

31. The latch of claim 22, wherein the keeper circuitry comprises two transistors of a same conductivity type.

32. A latch comprising:
a clock circuitry comprising at most two transistors of different conductivity types;
a keeper circuitry coupled to the clock circuitry;
a memory circuitry coupled to the keeper circuitry; and
a driver coupled to the memory circuitry, wherein the driver provides an output of the latch.

33. The latch of claim 32, further comprising:
an inverter to receive a data input and to generate an inverted data;
a first driver coupled to the clock circuitry and an input of the inverter; and
a second driver coupled to the clock circuitry and an output of the inverter, wherein the first driver and the second driver are coupled to the clock circuitry, the keeper circuitry, and the memory circuitry.

34. The latch of claim 33, wherein the keeper circuitry is coupled to an output of the first driver and an output of the second driver.

35. The latch of claim 33, wherein the memory circuitry coupled to the output of the first driver and the output of the second driver, and to the keeper circuitry.

36. The latch of claim 33, wherein the memory circuitry comprises cross-coupled NAND or NOR gates, wherein the cross-coupled NAND or NOR gates are coupled to the first driver, second driver, and the keeper circuitry.

37. The latch of claim 33, wherein the clock circuitry comprises:
a first n-type transistor coupled to the first driver and the second driver; and
a first p-type transistor coupled to the keeper circuitry, wherein gate terminals of the first n-type transistor and the first p-type transistor receive an input clock.

38. The latch of claim 37, wherein the first driver comprises:
a second n-type transistor coupled to the first n-type transistor of the clock circuitry; and
a second p-type transistor coupled in series with the second n-type transistor, wherein gate terminals of the second n-type transistor and the second p-type transistor are coupled to the input of the inverter, wherein drain terminals of the second p-type transistor and the second n-type transistor is coupled to the keeper circuitry and the memory circuitry.

39. The latch of claim 38, wherein the second driver comprises:
a third n-type transistor coupled to the first n-type transistor of the clock circuitry; and
a third p-type transistor coupled in series with the third n-type transistor, wherein gate terminals of the third n-type transistor and the third p-type transistor are coupled to the output of the inverter, wherein drain terminals of the third p-type transistor and the third n-type transistor is coupled to the keeper circuitry and the memory circuitry.

40. The latch of claim 32, wherein the keeper circuitry comprises two transistors of a same conductivity type.

41. A system comprising:
a processor, wherein the processor includes a latch, and wherein the latch includes:
an inverter to receive a data input and to generate an inverted data;
a clock circuitry comprising at most two transistors of different conductivity types;
a first driver coupled to the clock circuitry and an input of the inverter;
a second driver coupled to the clock circuitry and an output of the inverter;
a keeper circuitry coupled to an output of the first driver and an output of the second driver; and
a memory circuitry coupled to the output of the first driver, the output of the second driver, and the keeper circuitry; and
a memory coupled to the processor; and
a wireless interface communicatively coupled to the processor.

42. The system of claim 41, wherein the clock circuitry comprises:
a first n-type transistor coupled to the first driver and the second driver; and
a first p-type transistor coupled to the keeper circuitry, wherein gate terminals of the first n-type transistor and the first p-type transistor receive an input clock.

43. The system of claim 42,
wherein the first driver comprises:
a second n-type transistor coupled to the first n-type transistor of the clock circuitry; and
a second p-type transistor coupled in series with the second n-type transistor, wherein gate terminals of the second n-type transistor and the second p-type transistor are coupled to the input of the inverter, wherein drain terminals of the second p-type transistor and the second n-type transistor are coupled to the keeper circuitry and the memory circuitry; and
wherein the second driver comprises:
a third n-type transistor coupled to the first n-type transistor of the clock circuitry; and
a third p-type transistor coupled in series with the third n-type transistor, wherein gate terminals of the third n-type transistor and the third p-type transistor are coupled to the output of the inverter, wherein drain terminals of the third p-type transistor and the third n-type transistor is coupled to the keeper circuitry and the memory circuitry.

44. The system of claim 43, wherein the keeper circuitry comprises:
a fourth p-type transistor coupled to the first p-type transistor of the clock circuitry, and to the drain terminals of the second p-type transistor and the second n-type transistor of the first driver; and
a fifth p-type transistor coupled to first p-type transistor of the clock circuitry, and to the drain terminals of the third p-type transistor and the third n-type transistor of the second driver.

45. The system of claim 44, wherein the memory circuitry comprises:
a first NAND gate having a first input coupled to the drain terminals of the second p-type transistor and the second n-type transistor of the first driver, and a second input coupled to a gate terminal of the fourth p-type transistor of the keeper circuitry; and
a second NAND gate having a first input coupled to the drain terminals of the third p-type transistor and the third n-type transistor of the second driver, and to an output of the first NAND gate, and a second input coupled to a gate terminal of the fifth p-type transistor of the keeper circuitry.

46. The system of claim 41, further comprising a third driver coupled to the memory circuitry, wherein the third driver provides an output of the latch.
